(19) United States
(12) Patent Application Publication
(10) Pub. No.: US 2006/0006441 A1
(43) Pub. Date: Jan. 12, 2006

(54) Semiconductor device including a trench-type metal-insulator-metal (MIM) capacitor and method of fabricating the same

(76) Inventors: Duk-seo Park, Suwon-si (KR); Hyung-moo Park, Yongin-si (KR)

Correspondence Address: LEE, STERBA & MORSE P.C., SUITE 2000, 1101 WILSON BOULEVARD, ARLINGTON, VA, 22209, US

(21) Appl. No.: 11/099,678

(22) Filed: Apr. 6, 2005

(30) Foreign Application Priority Data
Jul. 8, 2004 (KR) 10-2004-0052971

(51) Int. Cl. H01L 27/108; H01L 21/8242

(52) U.S. Cl. 257/296; 438/239

(57) ABSTRACT

In a semiconductor device, and a method of fabricating the same, the semiconductor device includes a bottom electrode and a first interconnection layer on a semiconductor substrate, an upper surface of the bottom electrode and an upper surface of the first interconnection layer being level, an interlayer insulating layer having a trench exposing the upper surface of the bottom electrode and a via hole exposing the upper surface of the first interconnection layer, a contact plug formed of a first material inside the via hole and connected to the first interconnection layer, an upper electrode formed of a second material inside the trench on the bottom electrode, the first material being exclusive of the second material, and a dielectric layer interposed between the bottom electrode and the upper electrode, and formed only inside the trench.

### BACKGROUND OF THE INVENTION

1. Field of the Invention

The present invention relates to a semiconductor device and a method of fabricating the same. More particularly, the present invention relates to a semiconductor device including a trench-type metal-insulator-metal (MIM) capacitor and a method of fabricating the same.

2. Description of the Related Art

A capacitor as a passive component is used for various purposes in order to provide various logic circuits. Recently, demand for a capacitor having high capacitance has greatly increased. In particular, in the fabrication of a semiconductor device by employing analog circuits in a merged DRAM with logic (MDL), in which a DRAM and a logic circuit are merged, a metal-insulator-metal (MIM) capacitor as a capacitor of an analog circuit or a logic circuit is formed to provide the capacitance characteristics of the analog circuit.

FIGS. 1A through 1F illustrate cross-sectional views of processing sequences in a conventional method of fabricating a trench-type MIM

Referring to FIG. 1A, a first metal layer is formed on a semiconductor substrate 10, which is covered with an insulating layer (not shown) thereon. The first metal layer is then patterned using a photoresist pattern (not shown) as an etch mask on the semiconductor substrate 10, which is divided into a capacitor formation portion 10A and an interconnection formation portion 10B. This patterning concurrently forms a bottom electrode 12a and a first interconnection layer 12b on the semiconductor substrate 10.

An interlayer insulating layer 20 is then formed on the bottom electrode 12a and the first interconnection layer 12b, and the interlayer insulating layer 20 is dry-etched to form a trench 22 exposing the upper surface of the bottom electrode 12a. A dielectric layer 24 is then formed on the bottom electrode 12a, inner sidewalls of the trench 22, and an upper surface of the interlayer insulating layer 20.

Referring to FIG. 1B, the dielectric layer 24 and the interlayer insulating layer 20 are sequentially dry-etched in the interconnection formation portion 10B to form a via hole 26 exposing an upper surface of the first interconnection layer 12b. A sputtering etch process is then performed using RF (radio frequency) bias to remove any etch residue or native oxide layer, which may remain on the exposed surface of the first interconnection layer 12b.

Referring to FIG. 1C, a tungsten (W) layer 30 is deposited on the semiconductor substrate 10 having the trench 22 and the via hole 26 formed therein, to completely fill the via hole 26.

Referring to FIG. 1D, the tungsten layer 30 and the dielectric layer 24 under the tungsten layer 30 are polished by a chemical mechanical polishing (CMP) technique until the interlayer insulating layer 20 is exposed. As a result, a tungsten pattern 30a is formed inside the trench 22, and a tungsten plug 30b is formed inside the via hole 26 to fill the via hole 26.

Referring to FIG. 1E, a second metal layer 40 is formed on an entire surface of the resultant structure having the tungsten pattern 30a and the tungsten plug 30b.

Referring to FIG. 1F, the second metal layer 40 is patterned using a photoresist pattern (not shown) as an etch mask, thereby forming an interconnection layer 40a for an upper electrode on the tungsten pattern 30a in the capacitor formation portion 10A, and forming a second interconnection layer 40b on the tungsten plug 30b in the interconnection formation portion 10B.

As a result, a MIM capacitor, which is composed of the bottom electrode 12a, the dielectric layer 24, and an upper electrode 50, i.e., a stack structure of the tungsten pattern 30a and the interconnection layer 40a, is formed in the capacitor formation portion 10A of the semiconductor substrate 10. In the interconnection formation portion 10B, an interconnection structure is formed, in which the first interconnection layer 12b and the second interconnection layer 40b are sequentially stacked with the tungsten plug 30b between them, i.e., on and under the tungsten plug 30b, respectively.

In the conventional trench-type MIM capacitor as described above, the thin dielectric layer 24 may be vulnerable to damage due to the stress caused when the tungsten layer 30 is formed in the capacitor formation portion 10A, and the stress caused during the CMP process of the tungsten layer 30. A damaged portion of the dielectric layer 24 provides a path for leakage current. Furthermore, a thickness of the dielectric layer 24 in an edge portion E inside the trench 22 of the capacitor formation portion 10A becomes thinner than that in a central portion C due to normal deposition characteristics. Therefore, the strain of the tungsten layer 30 or the tungsten pattern 30a in the edge portion E of the trench 22 is rapidly changed, and thus, the elastic strain in the portion is rapidly changed, thereby causing the dielectric layer 24 to be damaged due to the volume change of the neighboring layers. In severe cases, the dielectric layer 24 in the edge portion E is torn off, thereby causing a short phenomenon between the bottom electrode 12a and the tungsten layer 30. As a result, the tungsten pattern 30a is separated from the dielectric layer 24.

Further, as described in reference to FIG. 1B, a sputtering etch process is performed using RF bias after the via hole 26 is formed. The sputtering etch process is performed when the dielectric layer 24 formed on the inner sidewalls of the trench 22 is exposed. As a result, the dielectric layer 24 may be damaged, thereby increasing a leakage current and increasing a capacitance deviation between capacitors inside a wafer, or from lot to lot.

### SUMMARY OF THE INVENTION

The present invention is therefore directed to a semiconductor device having a trench-type MIM capacitor and a method of fabricating the same, which substantially overcome one or more of the problems due to the limitations and disadvantages of the related art.

It is a feature of an embodiment of the present invention to provide a semiconductor device including a trench-type MIM capacitor that is capable of suppressing an increase of a leakage current by preventing damage to a dielectric layer due to a stress inside a trench for forming a capacitor.

It is another feature of an embodiment of the present invention to provide a method of fabricating a semiconductor device including a trench-type MIM capacitor that is able to eliminate causes of stress that may adversely affect a dielectric layer, suppress generation of damage to the dielectric layer, and thus, stably achieve a desired capacitance.

At least one of the above and other features and advantages of the present invention may be realized by providing a semiconductor device including a bottom electrode on a semiconductor substrate, a first interconnection layer on the semiconductor substrate, an upper surface of the bottom electrode and an upper surface of the first interconnection layer being level, an interlayer insulating layer having a trench exposing the upper surface of the bottom electrode and a via hole exposing the upper surface of the first interconnection layer, a contact plug formed of a first material inside the via hole, the contact plug connected to the first interconnection layer, an upper electrode formed of a second material inside the trench on the bottom electrode, the first material being exclusive of the second material, and a dielectric layer interposed between the bottom electrode and the upper electrode, and formed only inside the trench.

A width of the trench may be defined by sidewalls of the interlayer insulating layer on the bottom electrode, and the dielectric layer may be formed only on the upper surface of the bottom electrode and sidewalls of the interlayer insulating layer.

The semiconductor device may further include a second interconnection layer on the semiconductor substrate, the second interconnection layer having an upper surface that is level with an upper surface of the upper electrode, the second interconnection layer electrically connected to the first interconnection layer through the contact plug.

The upper electrode may include a barrier layer composed of one selected from the group consisting of titanium (Ti), titanium nitride (TiN), and a mixture thereof, and a metal layer composed of one selected from the group consisting aluminum (Al) and Al alloy.

At least one of the above and other features and advantages of the present invention may be realized by providing a semiconductor device including an interlayer insulating layer on a capacitor formation portion and an interconnection formation portion of a semiconductor substrate, a capacitor formed in the capacitor formation portion and penetrating the interlayer insulating layer, the capacitor including a bottom electrode, a dielectric layer, and an upper electrode formed of a first material, and a contact plug formed of a second material in the interconnection formation portion and penetrating the interlayer insulating layer, wherein the first material is exclusive of the second material.

The dielectric layer may be formed only on an upper surface of the bottom electrode and sidewalls of the interlayer insulating layer, and a portion of the upper electrode may directly contact an upper surface of the interlayer insulating layer.

At least one of the above and other features and advantages of the present invention may be realized by providing a method of fabricating a semiconductor device, including forming a bottom electrode and a first interconnection layer concurrently on a semiconductor substrate, the bottom electrode and the first interconnection layer being spaced apart from each other, forming an interlayer insulating layer covering the bottom electrode and the first interconnection layer concurrently, removing a first portion of the interlayer insulating layer to form a via hole exposing the first interconnection layer, filling the via hole with a conductive material to form a contact plug penetrating the interlayer insulating layer and connected to the first interconnection layer, removing a second portion of the interlayer insulating layer penetrated by the contact plug to form a trench exposing the bottom electrode, forming a dielectric layer only on an upper surface of the bottom electrode and sidewalls of the interlayer insulating layer, which are exposed within the trench, and forming an upper electrode on the dielectric layer.

Forming the dielectric layer may include depositing a dielectric material on the upper surface of the bottom electrode and the sidewalls of the interlayer insulating layer, which are exposed within the trench, and on an upper surface of the interlayer insulating layer and the contact plug, and removing the dielectric material from the upper surface of the interlayer insulating layer and the contact plug.

The dielectric layer may be formed of one selected from the group consisting of a silicon nitride layer and a mixture of a silicon nitride layer and a silicon oxide layer.

Forming the upper electrode may include forming a barrier layer composed of one selected from the group consisting of titanium (Ti), titanium nitride (TiN), and a mixture thereof, and forming a metal layer composed of one selected from the group consisting of aluminum (Al) and Al alloy.

The upper electrode and the contact plug may be composed of materials different from each other.

The method may further include forming a second interconnection layer on the interlayer insulating layer, being in contact with the contact plug, concurrently with the formation of the upper electrode.

In any embodiment of the present invention, the upper electrode and the second interconnection layer may be composed of a same material. The bottom electrode and the first interconnection layer may be composed of a same material. The contact plug may be composed of tungsten. A portion of the upper electrode may directly contact an upper surface of the interlayer insulating layer.

According to an embodiment of the present invention, a stress on a trench edge portion, which is structurally vulnerable during the fabrication of the trench-type MIM capacitor, may be reduced, and a generation of leakage current and device defects due to the damage or breakage of a dielectric layer may be prevented, thereby improving process stability. Further, damage to a dielectric layer and an increase of a leakage current due to a sputtering etch process may be prevented, thereby stably providing a desired capacitance.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A through 1F illustrate cross-sectional views of processing sequences in a conventional method of fabricating a trench-type MIM capacitor; and

FIGS. 2A through 2J illustrate cross-sectional views of processing sequences in a method of fabricating a trench-type MIM capacitor according to an embodiment of the present invention.

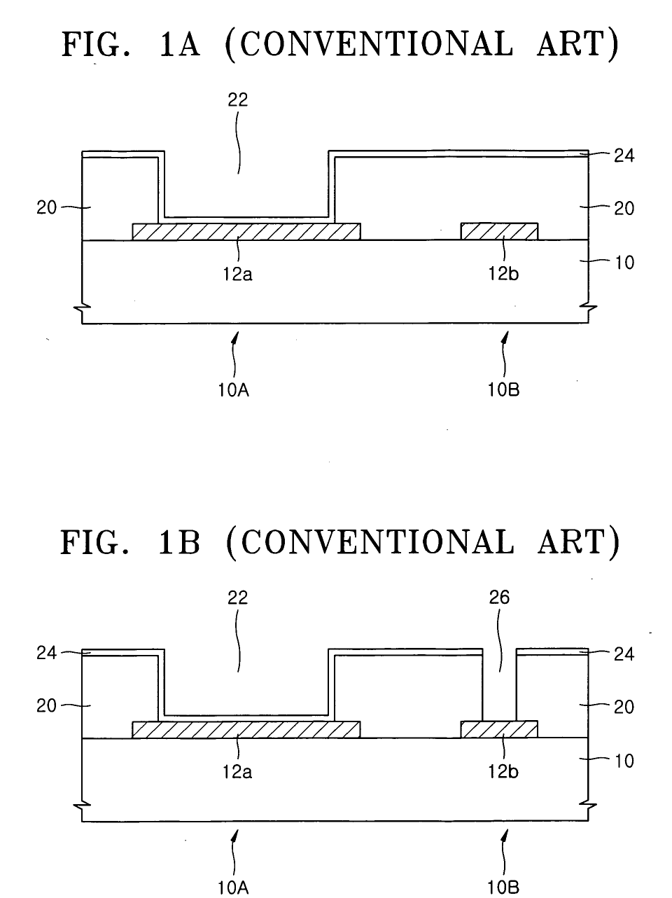

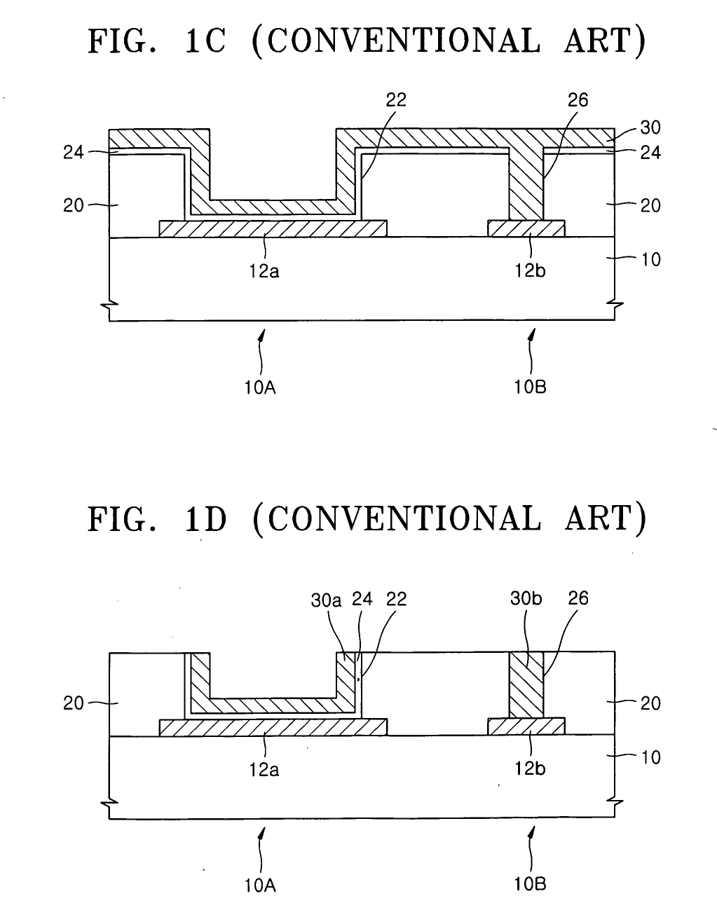

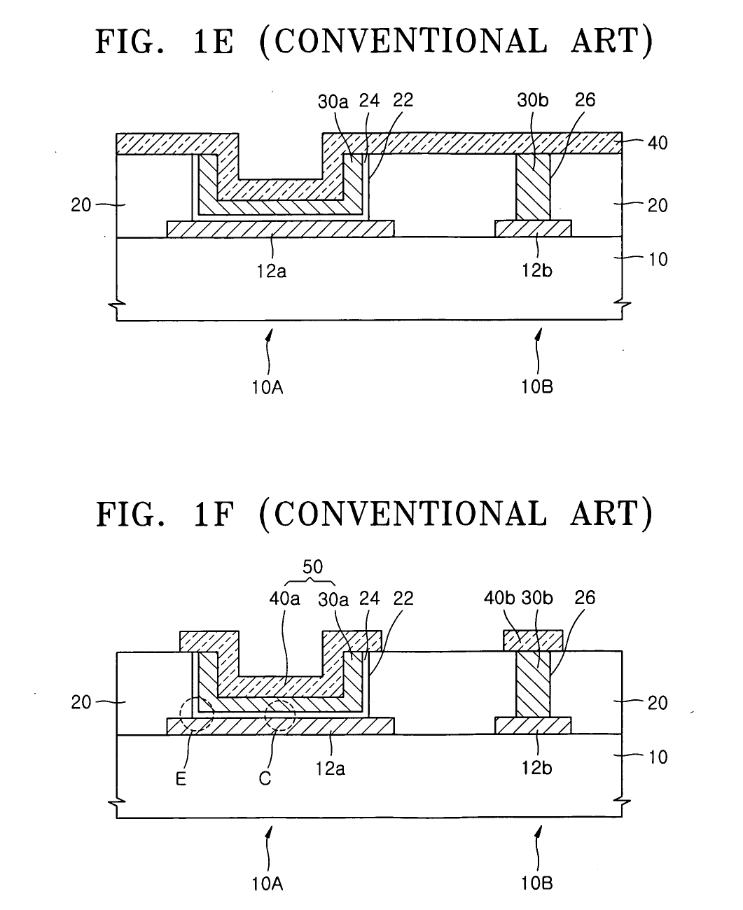

### DETAILED DESCRIPTION OF THE INVENTION

Korean Patent Application No. 2004-52971, filed on Jul. 8, 2004, in the Korean Intellectual Property Office, and entitled: “Semiconductor Device Having Trench-type Metal-Insulator-Metal Capacitor and Method of Fabricating the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

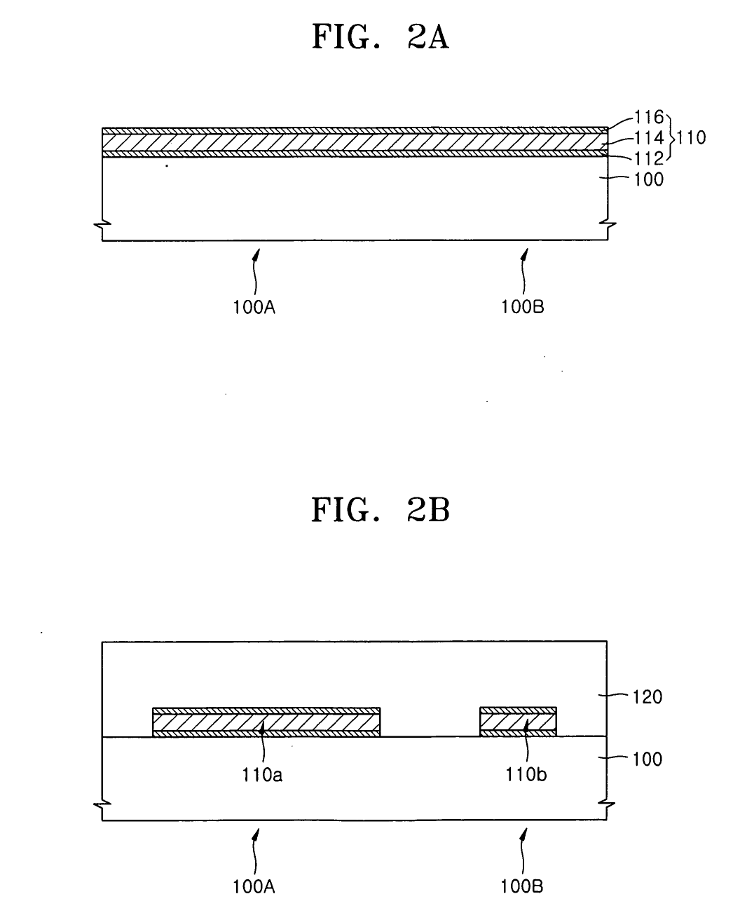

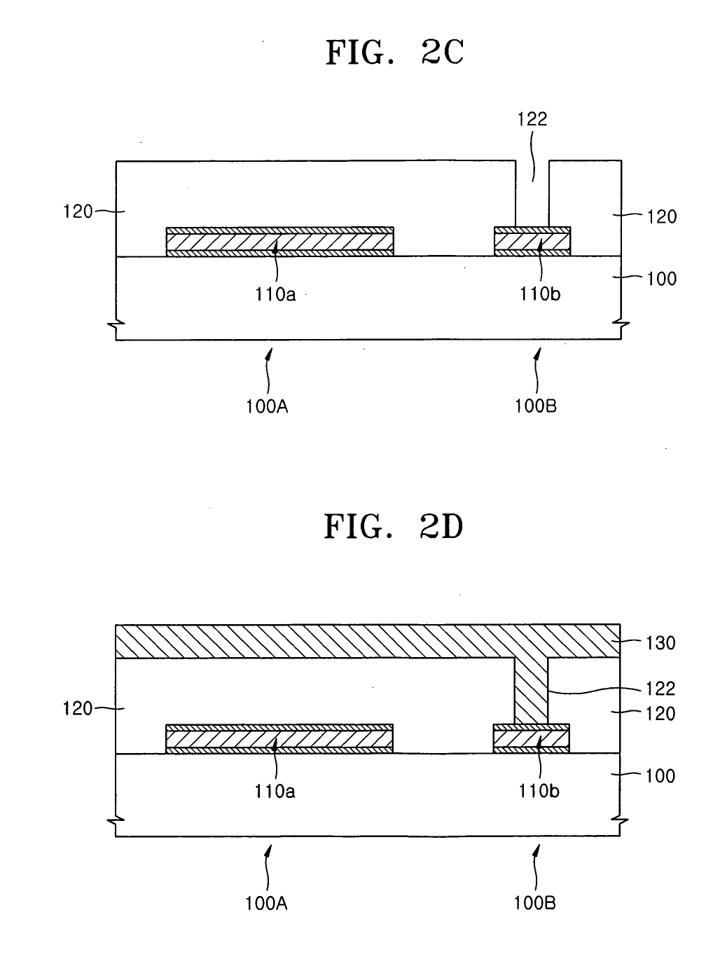

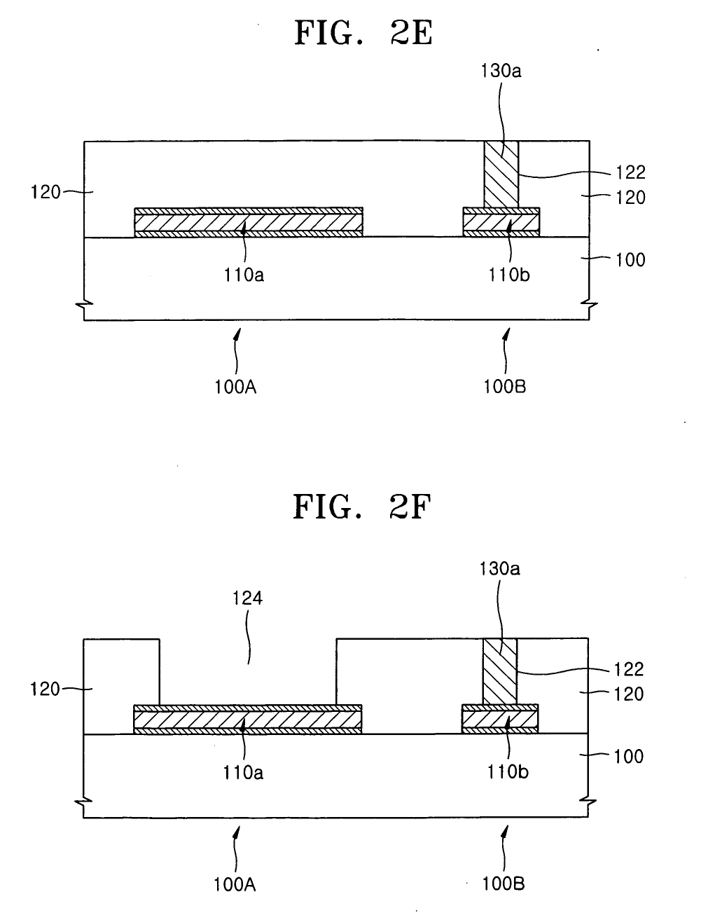

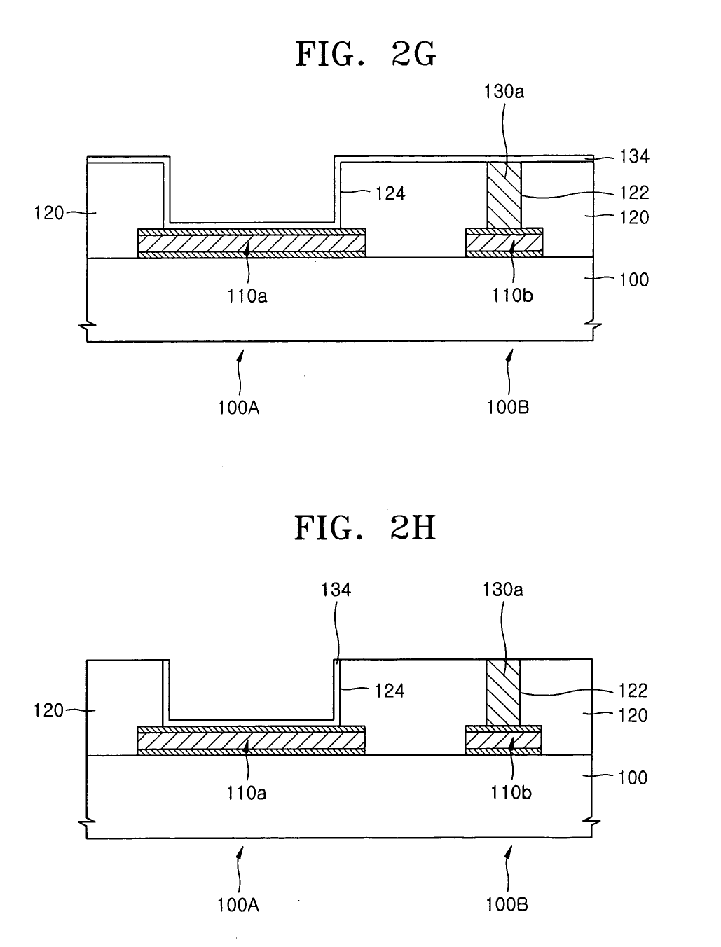

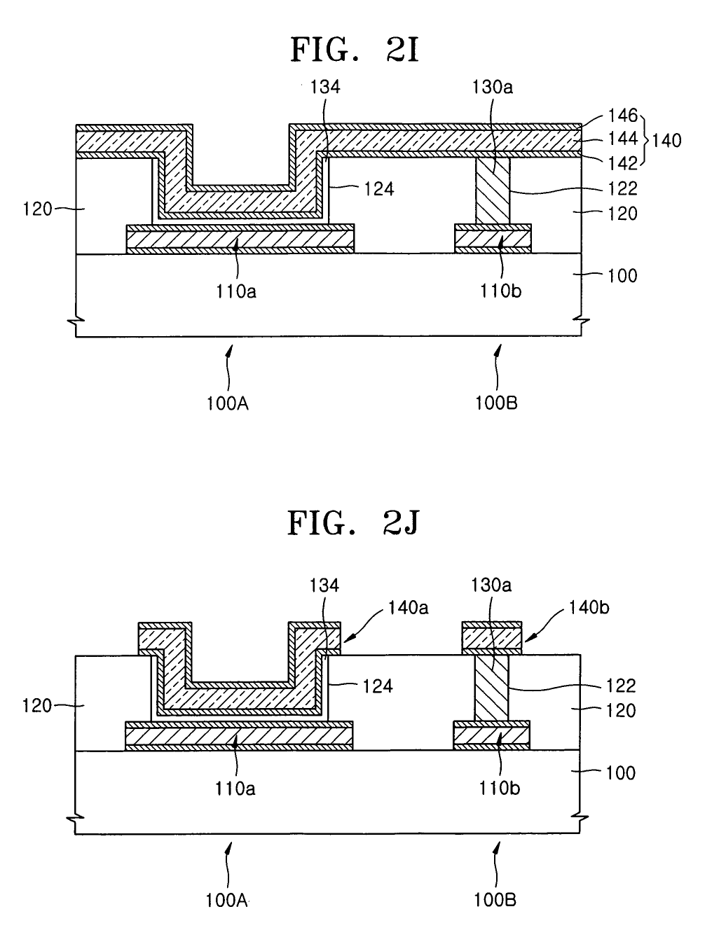

FIGS. 2A through 2J illustrate cross-sectional views of processing sequences in a method of fabricating a trench-type metal-insulator-metal (MIM) capacitor according to an embodiment of the present invention.

Referring to FIG. 2A, a first metal layer 110 is formed on a semiconductor substrate 100, which has a capacitor formation portion 100A and an interconnection formation portion 100B, the semiconductor substrate 100 being covered with an insulating layer (not shown) thereon. The first metal layer 110 may include a first barrier layer 112, a first aluminum (Al) containing layer 114, and a second barrier layer 116. The first barrier layer 112 and the second barrier layer 116 may be respectively composed of titanium (Ti), titanium nitride (TiN), or a mixture thereof. The first Al containing layer 114 may be composed of Al or Al alloy. For example, the first barrier layer 112 may be formed of a Ti layer having a thickness of about 150 Å, the first Al containing layer 114 may be formed of an Al layer having a thickness of about 5000 Å, and the second barrier layer 116 may be formed of a mixture of a Ti layer having a thickness of about 150 Å and a TiN layer having a thickness of about 650 Å. In some cases, the first barrier layer 112 and the second barrier layer 116 may be omitted.

Referring to FIG. 2B, using a photoresist pattern (not shown) as an etch mask, the first metal layer 110 is patterned, thereby concurrently forming a bottom electrode 110a and a first interconnection layer 110b on the semiconductor substrate 100 in the capacitor formation portion 100A and the interconnection formation portion 10B, respectively. An upper surface of the bottom electrode 110a and an upper surface of the first interconnection layer 110b are level, i.e., the bottom electrode 110a and the first interconnection layer 110b extend up from an upper surface of the semiconductor substrate 100 by a same distance.

An interlayer insulating layer 120 is then formed on the bottom electrode 110a and the first interconnection layer 110b. For example, the interlayer insulating layer 120 may include a F-doped silicate glass (FSG) film having a thickness of about 6500 Å and a plasma-enhanced tetraethylorthosilicate glass (p-TEOS) film having a thickness of about 16,000 Å.

Referring to FIG. 2C, using a photoresist pattern (not shown) as an etch mask, the interlayer insulating layer 120 in the interconnection formation portion 100B is dry-etched to form a via hole 122 exposing an upper surface of the first interconnection layer 110b. A sputtering etch process is then performed using RF bias to remove any etch residue or native oxide layer, which may exist on the exposed upper surface of the first interconnection layer 110b. The capacitor formation portion 100A is not affected by the sputtering etch process since the capacitor formation portion 100A is entirely covered by the interlayer insulating layer 120.

Referring to FIG. 2D, a tungsten (W) layer 130 is deposited over the semiconductor substrate 100, the tungsten layer 130 completely filling the via hole 122.

Referring to FIG. 2E, the tungsten layer 130 is then polished by a chemical mechanical polishing (CMP) process, or etch-backed until the interlayer insulating layer 120 is exposed. As a result, a contact plug 130a, which is composed of tungsten, is formed inside the via hole 122. The contact plug 130a penetrates the interlayer insulating layer 120, and is electrically connected to the first interconnection layer 110b.

Referring to FIG. 2F, the interlayer insulating layer 120 in the capacitor formation portion 100A is dry-etched using a photoresist pattern (not shown) as an etch mask to form a trench 124 exposing an upper surface of the bottom electrode 110a.

Referring to FIG. 2G, a dielectric layer 134 is formed on the upper surface of the bottom electrode 110a exposed by the trench 124, sidewalls of the interlayer insulating layer 120, the upper surface of the interlayer insulating layer 120, and an upper surface of the contact plug 130a. The dielectric layer 134 may be formed of, e.g., a silicon nitride layer or a mixture of a silicon nitride layer and a silicon oxide layer. The dielectric layer 134 may have a thickness of, e.g., about 800 Å.

Referring to FIG. 2H, the dielectric layer 134 is polished by a CMP technique until the interlayer insulating layer 120 is exposed. As a result, the dielectric layer 134 remains only within the trench 124, i.e., on the upper surface of the bottom electrode 110a and the sidewalls of the interlayer insulating layer 120.

Referring to FIG. 21, a second metal layer 140 is formed on an entire surface of the semiconductor substrate 100 to cover the dielectric layer 134 inside the trench 124. The second metal layer 140 may include a third barrier layer 142, a second Al containing layer 144, and a fourth barrier layer 146. The third barrier layer 142 and the fourth barrier layer 146 may be respectively composed of Ti, TiN, or a mixture thereof. The second Al containing layer 144 may be composed of Al or Al alloy. For example, the third barrier layer 142 may be formed of a Ti layer having a thickness of about 150 Å, the second Al containing layer 144 may be formed of an Al layer having a thickness of about 5000 Å, and the fourth barrier layer 146 may be formed of a mixture of a Ti layer having a thickness of about 150 Å and a TiN layer having a thickness of about 650 Å. In some cases, the third barrier layer 142 and the fourth barrier layer 146 may be omitted.

Referring to FIG. 2J, using a photoresist pattern (not shown) as an etch mask, the second metal layer 140 is patterned to form an upper electrode 140a on the dielectric layer 134 in the capacitor formation portion 100A and a second interconnection layer 140b on the contact plug 130a in the interconnection formation portion 10B. The upper electrode 140a includes a portion overlapping the upper surface of the interlayer insulating layer 120. Since the overlapping portion does not have the dielectric layer 134 under the upper electrode 140a, the overlapping portion of the upper electrode 140a directly contacts the upper surface of the interlayer insulating layer 120.

As a result of performing the above processes, a MIM capacitor, which is composed of the bottom electrode 110a, the dielectric layer 134, and the upper electrode 140a, is formed in the capacitor formation portion 100A of the semiconductor substrate 100. In the interconnection formation portion 10B, an interconnection structure is formed, in which the first interconnection layer 110b and the second interconnection layer 140b are sequentially stacked with the contact plug 130a therebetween, i.e., on and under the contact plug 130a, respectively.

As described above, the trench-type MIM capacitor according to an embodiment of the present invention is fabricated so that the via hole 122 and the contact plug 130a being composed of tungsten to fill the via hole 122 are first formed in the interlayer insulating layer 120, and then, the trench 124 is formed to fabricate the capacitor. As a result, a tungsten layer does not remain in the capacitor formation portion 100A, and the upper electrode 140a does not include a tungsten layer. Therefore, a stress to the dielectric layer 134 may be reduced, and a damage on the dielectric layer 134 caused by the stress may be prevented.

Therefore, in the method of fabricating a trench-type MIM capacitor according to an embodiment of the present invention, a plug, composed of tungsten, is formed in an interconnection formation portion, and a trench exposing a bottom electrode is formed. Then, a dielectric layer and an upper electrode are formed in the trench, thereby completing the fabrication of a capacitor. Thus, a tungsten layer does not remain in a capacitor formation portion, and an upper electrode without the tungsten layer is achieved. Therefore, a stress on the trench edge portion, which is structurally vulnerable during the fabrication of the trench-type MIM capacitor, may be reduced, and the generation of leakage current and device defects due to damage to or breakage of the dielectric layer may be prevented, thereby improving process stability. Further, since a sputtering etch process using RF bias after the formation of a via hole is performed before the trench is formed in the capacitor formation portion, damage to the dielectric layer and the increase of leakage current due to the sputtering etch process may be prevented, thereby stably providing a desired capacitance.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a bottom electrode on a semiconductor substrate;
a first interconnection layer on the semiconductor substrate, an upper surface of the bottom electrode and an upper surface of the first interconnection layer being level;
an interlayer insulating layer having a trench exposing the upper surface of the bottom electrode and a via hole exposing the upper surface of the first interconnection layer;
a contact plug formed of a first material inside the via hole, the contact plug connected to the first interconnection layer;
an upper electrode formed of a second material inside the trench on the bottom electrode, the first material being exclusive of the second material; and
a dielectric layer interposed between the bottom electrode and the upper electrode, and formed only Inside the trench.

2. The semiconductor device as claimed in claim 1, wherein a width of the trench is defined by sidewalls of the interlayer insulating layer on the bottom electrode, and
the dielectric layer is formed only on the upper surface of the bottom electrode and sidewalls of the interlayer insulating layer.

3. The semiconductor device as claimed in claim 1, further comprising a second interconnection layer on the semiconductor substrate, the second interconnection layer having an upper surface that is level with an upper surface of the upper electrode, the second interconnection layer electrically connected to the first interconnection layer through the contact plug.

4. The semiconductor device as claimed in claim 3, wherein the upper electrode and the second interconnection layer are composed of a same material.

5. The semiconductor device as claimed in claim 1, wherein the bottom electrode and the first interconnection layer are composed of a same material.

6. The semiconductor device as claimed in claim 1, wherein a portion of the upper electrode directly contacts an upper surface of the interlayer insulating layer.

7. The semiconductor device as claimed in claim 1, wherein the upper electrode comprises:
a barrier layer composed of one selected from the group consisting of titanium (Ti), titanium nitride (TiN), and a mixture thereof, and
a metal layer composed of one selected from the group consisting aluminum (Al) and Al alloy.

8. The semiconductor device as claimed in claim 1, wherein the contact plug is composed of tungsten.

9. A semiconductor device, comprising:
an interlayer insulating layer on a capacitor formation portion and an interconnection formation portion of a semiconductor substrate;
a capacitor formed in the capacitor formation portion and penetrating the Interlayer Insulating layer, the capacitor including
a bottom electrode,
a dielectric layer, and
an upper electrode formed of a first material; and
a contact plug formed of a second material in the interconnection formation portion and penetrating the interlayer insulating layer,
wherein the first material is exclusive of the second material.

10. The semiconductor device as claimed in claim 9, wherein the dielectric layer is formed only on an upper surface of the bottom electrode and sidewalls of the interlayer insulating layer, and a portion of the upper electrode directly contacts an upper surface of the interlayer insulating layer.

11. A method of fabricating a semiconductor device, comprising:
forming a bottom electrode and a first interconnection layer concurrently on a semiconductor substrate, the bottom electrode and the first interconnection layer being spaced apart from each other,
forming an interlayer insulating layer covering the bottom electrode and the first interconnection layer concurrently;
removing a first portion of the interlayer insulating layer to form a via hole exposing the first interconnection layer;
filling the via hole with a conductive material to form a contact plug penetrating the interlayer insulating layer and connected to the first interconnection layer;
removing a second portion of the interlayer insulating layer penetrated by the contact plug to form a trench exposing the bottom electrode;
forming a dielectric layer only on an upper surface of the bottom electrode and sidewalls of the interlayer insulating layer, which are exposed within the trench; and
forming an upper electrode on the dielectric layer.

12. The method as claimed in claim 11, wherein the contact plug is composed of tungsten.

13. The method as claimed in claim 11, wherein forming the dielectric layer comprises:
depositing a dielectric material on the upper surface of the bottom electrode and the sidewalls of the interlayer insulating layer, which are exposed within the trench, and on an upper surface of the interlayer insulating layer and the contact plug; and
removing the dielectric material from the upper surface of the interlayer insulating layer and the contact plug.

14. The method as claimed in claim 11, wherein the dielectric layer is formed of one selected from the group consisting of a silicon nitride layer and a mixture of a silicon nitride layer and a silicon oxide layer.

15. The method as claimed in claim 11, wherein the bottom electrode and the first interconnection layer are composed of a same material.

16. The method as claimed in claim 11, wherein forming the upper electrode comprises:
forming a barrier layer composed of one selected from the group consisting of titanium (Ti), titanium nitride (TiN), and a mixture thereof; and
forming a metal layer composed of one selected from the group consisting of aluminum (Al) and Al alloy.

17. The method as claimed in claim 11, wherein the upper electrode and the contact plug are composed of materials different from each other.

18. The method as claimed in claim 11, further comprising forming a second interconnection layer on the interlayer insulating layer, being in contact with the contact plug, concurrently with the formation of the upper electrode.

19. The method as claimed In claim 18, wherein the upper electrode and the second interconnection layer are composed of a same material.

20. The method as claimed in claim 11, wherein a portion of the upper electrode directly contacts an upper surface of the interlayer insulating layer.
